(19) United States
(12) Patent Application Publication
(10) Pub. No.: US 2018/0223448 A1
(43) Pub. Date: Aug. 9, 2018

(54) APPARATUS AND METHOD FOR SEMICONDUCTOR POLYCRYSTALLIZATION

(71) Applicant: BOE TECHNOLOGY GROUP CO., LTD., Beijing (CN)

(72) Inventor: Yoonsung Um, Beijing (CN)

(73) Assignee: BOE TECHNOLOGY GROUP CO., LTD., Beijing (CN)

(21) Appl. No.: 15/571,629

(22) PCT Filed: Jun. 1, 2017
(86) PCT No.: PCT/CN2017/086797

§ 371 Date: Nov. 3, 2017

(30) Foreign Application Priority Data
Jul. 14, 2016 (CN) 201610556752.5

(51) Int. Cl. C30B 28/02; C30B 33/02; H01L 21/02; H01L 21/67

(52) U.S. Cl. CPC C30B 28/02; C30B 33/02; H01L 21/02532; H01L 21/67109; H01L 21/02565; H01L 21/02667; H01L 21/02554

(57) ABSTRACT

Apparatus and method for semiconductor polycrystallization are provided. The apparatus includes a plurality of ejector outlets for ejecting a heated gas to polycrystallize an amorphous semiconductor to produce a polycrystalline semiconductor.

### CROSS-REFERENCE TO RELATED APPLICATION

This PCT patent application claims priority to Chinese Patent Application No. 201610556752.5, filed on Jul. 14, 2016, the entire content of which is incorporated by reference herein.

### TECHNICAL FIELD

The present disclosure generally relates to display technologies and, more particularly, relates to an apparatus and a method for semiconductor polycrystallization.

### BACKGROUND

In recent years, low temperature poly-silicon (LTPS) technology continues to develop. A liquid crystal (LC) display panel formed from LTPS technology often has a higher aperture ratio, enabling the display panel to have higher brightness level and lower power consumption. This type of LC display panels is thus more suitable to form thinner products with lower power consumption and higher resolution. Accordingly, an apparatus and a method for polycrystallizing amorphous semiconductors are desired.

### SUMMARY

One aspect of present disclosure includes an apparatus for semiconductor polycrystallization. The apparatus includes a plurality of ejector outlets for ejecting a heated gas to polycrystallize an amorphous semiconductor to produce a polycrystalline semiconductor.

Optionally, one ejector outlet corresponds to a gas-receiving region on the amorphous semiconductor and corresponds to a non-gas-receiving region neighboring the gas-receiving region on the amorphous semiconductor such that amorphous semiconductor in the gas-receiving region is converted into polycrystalline semiconductor by the heated gas. A diffusion rate of heat generated by the heated gas ejected by the ejector outlet from the gas-receiving region to the non-gas-receiving region is fast enough so that a gas-receiving region of a substrate deposited with the amorphous semiconductor is undamaged by the heated gas.

Optionally, the diffusion rate of heat generated by the heated gas ejected by the ejector outlet is associated with dimensions of the ejector outlet and a distance between two adjacent ejector outlets.

Optionally, a ratio of a total area of gas-receiving regions correspond to the plurality of ejector outlets to a total area of non-gas-receiving regions correspond to the plurality of ejector outlets is in a range of about 1:1000 to about 1000:1.

Optionally, the plurality of ejector outlets is arranged in an array.

Optionally, the apparatus further includes a mask containing the ejector outlets.

Optionally, a ratio of a total area of the plurality of ejector outlets over a total area of areas other than the ejector outlets on the mask is in a range from about 1:1000 to about 1000:1.

Optionally, the apparatus further includes a spray gun for spraying heated gas over a large area on the mask.

Optionally, the apparatus further includes a cooling apparatus for cooling down the substrate deposited with the amorphous semiconductor.

Optionally, the amorphous semiconductor includes at least one of an amorphous silicon and an amorphous oxide.

Optionally, a temperature of the heated gas is higher than about 800° C. for converting the amorphous silicon into a polycrystalline silicon.

Optionally, a temperature of the heated gas is higher than about 300° C. for converting the amorphous oxide into a polycrystalline oxide.

Optionally, a temperature of the heated gas is higher than about 200° C. for annealing the amorphous oxide.

Another aspect of present disclosure includes method for semiconductor polycrystallization by using the disclosed apparatus to eject the heated gas on the amorphous semiconductor to polycrystallize the amorphous semiconductor into the polycrystalline semiconductor.

Optionally, the method further includes periodically ejecting the heated gas to the amorphous semiconductor.

Optionally, the periodically ejecting includes a ratio of an ejecting time length over a non-ejecting time length of about 1:10000 or greater.

Optionally, the method further includes moving the apparatus, after one ejection process that converts a portion of the amorphous semiconductor into the polycrystalline semiconductor, to anther portion of the amorphous semiconductor to convert the another portion of the amorphous semiconductor into another portion of the polycrystalline semiconductor.

Optionally, the amorphous semiconductor is made of an amorphous silicon and a temperature of the heated gas for the polycrystallization is higher than about 800° C.

Optionally, the amorphous semiconductor is made of an amorphous oxide semiconductor and a temperature of the heated gas for the polycrystallization is above about 300° C.

Optionally, the amorphous semiconductor is made of an amorphous oxide semiconductor and a temperature of the heated gas for annealing the amorphous oxide semiconductor is higher than about 200° C.

### BRIEF DESCRIPTION OF THE FIGURES

The following drawings are merely examples for illustrative purposes according to various disclosed embodiments and are not intended to limit the scope of the present disclosure.

FIG. 1 illustrates an exemplary operation of a disclosed apparatus for semiconductor polycrystallization according to various disclosed embodiments of the present disclosure;

FIG. 2 illustrates an exemplary mask in an exemplary apparatus for semiconductor polycrystallization according to various disclosed embodiments of the present disclosure; and

FIG. 3 illustrates another exemplary mask in an exemplary apparatus for semiconductor polycrystallization according to various disclosed embodiments of the present disclosure.

### DETAILED DESCRIPTION

The disclosure will now describe more specifically with reference to the following embodiments. It is to be noted that the following descriptions of some embodiments are presented herein for purpose of illustration and description only. It is not intended to be exhaustive or to be limited to the precise form disclosed.

In the following description, numerous specific details are set forth in order to provide a thorough understanding of the present disclosure, but the disclosure may be embodied or implemented in other specific forms than those described herein. Thus, the scope of the disclosure should not be limited by the specific embodiments of the present disclosure.

In one aspect, the present disclosure provides an apparatus for semiconductor polycrystallization. The disclosed apparatus may eject heated gas to an amorphous semiconductor substrate, to polycrystallize the amorphous semiconductor such that the amorphous semiconductor over an amorphous semiconductor substrate may be converted to polycrystalline semiconductor.

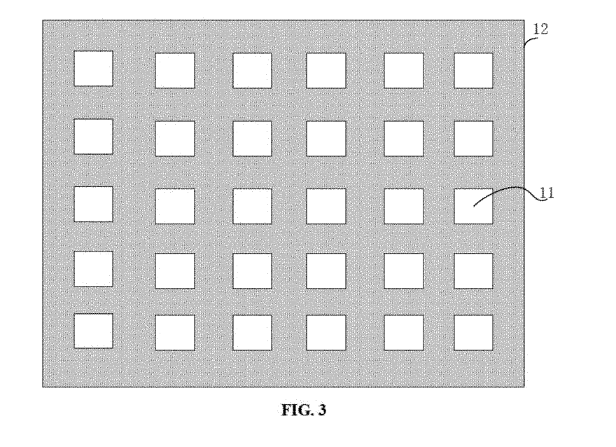

As shown in FIGS. 1, 2, and 3, in one embodiment, the disclosed apparatus 1 may include a plurality of ejector outlets 11. The disclosed apparatus 1 for semiconductor polycrystallization may eject heated gas to an amorphous semiconductor layer over a substrate 22. The amorphous semiconductor layer and the substrate 22 may form an amorphous semiconductor substrate. An ejector outlet 11 may be facing or correspond to a gas-receiving region in the amorphous semiconductor substrate and may eject heated gas onto the corresponding gas-receiving region to convert the amorphous semiconductor to polycrystalline semiconductor. A non-gas-receiving region may be a region, corresponding to an ejector outlet 11, in the amorphous semiconductor substrate where the amorphous semiconductor is not desired to be converted to polycrystalline semiconductor. The non-gas-receiving region corresponding to an ejector outlet 11 may be neighboring the gas-receiving region corresponding to the ejector outlet 11 such that heat may be transferred from the gas-receiving region to the non-gas-receiving region. The dimensions of an ejector outlet 11 and a distance arranged between two adjacent ejector outlets 11 may enable the heat provided by the heated gas, ejected by an ejector outlet and transferred from the corresponding gas-receiving region to the corresponding non-gas-receiving region, to have a desired conduction/diffusion rate. The diffusion rate may be faster than a first heat diffusion speed, where the first speed represents the minimum heat diffusion speed at which the gas-receiving area of substrate 22 can be damaged by the heat generated by the gas ejected onto it surface. As shown in FIG. 1, the arrows along the vertical direction may represent the direction of heated gas, ejected from the ejector outlets 11. The arrows along the horizontal direction may represent the directions of heat transfer/conduction, in the amorphous semiconductor substrate.

The disclosed apparatus may also include a spray gun (not shown) and a mask 12. The plurality of ejector outlets 11 may be arranged in the mask 12. The disclosed apparatus may further include a cooling apparatus 13. The cooling apparatus 13 may cool the substrate 22 when the amorphous semiconductor layer 21 is being polycrystallized by the disclosed apparatus.

In one embodiment, by ejecting heated gas to the amorphous semiconductor substrate through the ejector outlets 11, the heat provided by the heated gas may convert the amorphous semiconductor in the amorphous semiconductor layer 21 to polycrystalline semiconductor. Thus, amorphous semiconductor may be polycrystallized to polycrystalline semiconductor.

In one embodiment, the dimensions of an ejector outlet 11 and the distance between two adjacent ejector outlets 11 may enable the heat provided by the heated gas, ejected by an ejector outlet from the corresponding gas-receiving region to the corresponding non-gas-receiving region, to have a diffusion rate higher than the first speed. Accordingly, the diffusion rate of the heat in heated gas ejected by an ejector outlet 11, when transferred from the gas-receiving region to the non-gas-receiving region, may be desirably high. Thus, the substrate 22 of the amorphous semiconductor layer 21 may be less susceptible to damages caused by instantaneous heat transfer. Damages to the substrate 22 during the polycrystallization of the amorphous semiconductor layer 21, can be reduced or avoided.

In practice, it may be desired that the dimensions of an ejector outlet 11 and the distance between two adjacent ejector outlets 11 may enable the heat provided by the heated gas, ejected by an ejector outlet from the corresponding gas-receiving region to the corresponding non-gas-receiving region, to have a diffusion rate higher than the first speed. The specific shape and dimensions of an ejector outlet 11 and the distance between two adjacent ejector outlets 11 should be determined according to different designs/applications and should not be limited by the embodiments of the present disclosure.

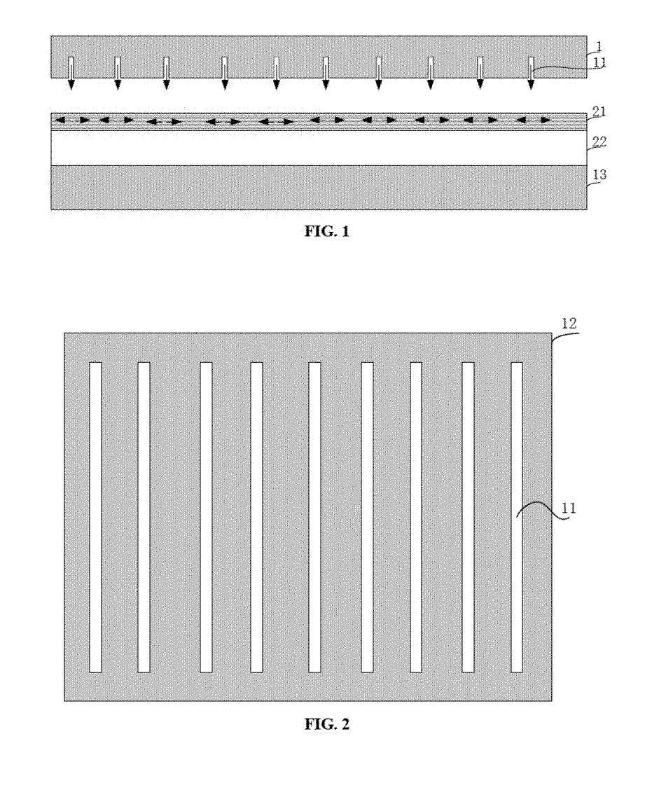

For example, an ejector outlet 11 may be the strip-shaped ejector outlet 11 shown in FIG. 2. The strip-shaped ejector outlets 11 may be parallel to each other, and the width of an ejector outlet 11 may be in a range of about 35 μm to about 45 μm. If the distance between two adjacent ejector outlets 11 is sufficiently small, the heat of the heated gas may not be diffused well. Due to this consideration, the distance between two adjacent ejector outlets 11 may be greater than the width of an ejector outlet 11. In one embodiment, the distance between two adjacent ejector outlets 11 may be about 3.5 to about 4.5 times the width of an ejector outlet 11. In another embodiment, an ejector outlet 11 may have a rectangular shape or a circular shape and the plurality of ejector outlets 11 may be arranged in an array. The plurality of ejector outlets may also be arranged in other suitable configurations, e.g., staggered arrangement, circular arrangement. An ejector outlet may also have various suitable shapes to convert amorphous semiconductor layer 21 of different shapes to polycrystalline semiconductor. An ejector outlet 11 may be of a cylindrical shape outlet (FIG. 1), of a cone shaped cross section, as well as other suitable shapes. The dimensions of an ejector outlet 11 and the distance between two adjacent ejector outlets 11 may be determined according to different applications and/or designs and should not be limited by the embodiments of the present disclosure.

In some embodiments, when the disclosed apparatus for semiconductor polycrystallization 1 is performing a polycrystallization process on an amorphous semiconductor layer 21 and the substrate 22, after ejecting the heated gas over the amorphous semiconductor layer 21 to convert a portion of the amorphous semiconductor layer 21 to polycrystalline semiconductor, the disclosed apparatus may move to covert the amorphous semiconductor of the entire amorphous semiconductor layer 21 to polycrystalline semiconductor. The ratio between the corresponding gas-receiving region to the corresponding non-gas-ejection region, of an ejector outlet 11, may be desirably high. A higher ratio may correspond to a smaller number of gas ejections and a shorter time for the polycrystallization process. However, a higher ration may also cause the heat dissipation to be more difficult, and the substrate 22 may be more susceptible to damages. Thus, besides the dimension of an ejector outlet 11 and the distance between two adjacent ejector outlets 11 being in a desirable range to enable the heat of the heated gas to diffuse in a rate higher than the first speed from the corresponding gas-receiving region to the corresponding non-gas-receiving region, the ratio between the total area of the gas-receiving regions and the total area of the gas-receiving regions may be within a desired range, e.g., from about 1:1000 to about 1000:1. The specific value of the ratio should be determined according to different designs and/or applications and should not be limited by the embodiments of the present disclosure.

In some embodiments, a ratio of a total area of the plurality of ejector outlets over a total area of areas other than the ejector outlets on the mask is in a range from about 1:1000 to about 1000:1.

In some embodiments, the damages to the substrate 22 during the polycrystallization process may also be reduced using other methods, besides the method of reducing the dimensions of an ejector outlet 11 or the distance between two adjacent ejector outlets 11. For example, the ejection speed and the temperature of the heated gas may be adjusted to desirable ranges to ensure no damages occur to the substrate 22. Any suitable methods to reduce or eliminate the damages to the substrate 22 should be within the scope of the present disclosure.

In one embodiment, because the disclosed apparatus may include a spray gun and a mask 12, and the plurality of ejector outlets 11 is arranged in the mask 12, the mask 12 may disperse or diffuse the gas sprayed by the spray gun, over a large area over the mask 12, such that the heated gas may be ejected from the ejector outlets 11 in the mask 12. Thus, when a portion of the amorphous semiconductor layer 21, over the substrate 22, is not ejected with the heated gas, the spray gun and the mask 12 may enable the portions of the amorphous semiconductor layer 21 and the substrate 22, ejected with the heated gas, to transfer or diffuse the heat to the portions of the amorphous semiconductor layer 21 and the substrate not ejected with the heated gas. Heat may be more uniformly distributed. Damages to the portions of the amorphous semiconductor layer 21 and the substrate 22, caused by the heat transferred by the heated gas, can be reduced or eliminated.

In some other embodiments, the disclosed apparatus for semiconductor polycrystallization 1 may not include a spray gun and a mask 12. Other suitable methods may also be used to eject heated gas from the plurality of ejector outlets. Any methods and apparatuss for implementing the aforementioned function of improving the uniformity of heat transfer should also be within the scope of the present disclosure.

In one embodiment, because the disclosed apparatus for semiconductor polycrystallization 1 also includes a cooling apparatus 13 to cool down the substrate 22, damages to the amorphous semiconductor layer 21 and the substrate 22, caused by heat transferred by the heated gas during the polycrystallization process, can be reduced or eliminated.

In some embodiments, the cooling apparatus 13 may have various different structures. For example, the cooling apparatus 13 may be a metal-made workbench/grid, and the heat from the substrate 22 may be dissipated through metal heat conduction. In another example, a water cooling apparatus 13 may be applied to cool down the substrate 22. The specific type of water cooling apparatus may be selected according to different designs and/or applications and should not be limited by the embodiments of the present disclosure.

In some other embodiments, the disclosed apparatus for semiconductor polycrystallization may not include a cooling apparatus 13. However, any suitable apparatuss or methods for cooling the substrate 22 should be within the scope of the present disclosure.

In some embodiments, the temperature of the heated gas, ejected by the disclosed apparatus for semiconductor crystallization may be determined according to actual needs.

Another aspect of the present disclosure provides a method for polycrystallizing an amorphous semiconductor substrate. The method may include using the disclosed apparatus for semiconductor polycrystallization to eject heated gas to an amorphous semiconductor substrate. The disclosed apparatus for semiconductor polycrystallization may be the apparatus 1 shown in FIG. 1, and may also be other suitable apparatuses derived from the disclosed apparatus 1 in various embodiments.

The disclosed method for polycrystallizing an amorphous semiconductor substrate may include applying the disclosed apparatus for semiconductor polycrystallization, illustrated in previous embodiments, to polycrystallize an amorphous semiconductor substrate. The advantages of using the disclosed method may be similar to those of using the disclosed apparatus and are not repeated herein.

In some embodiments, the disclosed apparatus for semiconductor polycrystallization may periodically eject heated gas to the amorphous semiconductor substrate. That is, the disclosed apparatus may eject heated gas to the amorphous semiconductor substrate for a certain amount of time and stop ejecting heated gas, such that the heat from the substrate 22 may be fully diffused. The disclosed apparatus may start ejecting heated gas again until the amorphous semiconductor of the amorphous semiconductor layer 21, in the gas-receiving region, is fully converted to polycrystalline semiconductor. The time of gas ejection during one period may be determined based on various relevant factors such as the temperature of the gas, the area of a gas-receiving region, and the materials of the amorphous semiconductor layer 21 and the substrate 22.

For example, the periodical ejection of the heated gas may include a ratio of an ejecting time length over a non-ejecting time length. Such ratio may be about 1:10000 or greater. In various embodiments, such ratio may be about 1:10000, having about 0.01 second for ejection and about 100 seconds for non-ejection; or may be about 1:1000, having about 0.01 second for ejection and about 10 seconds for non-ejection; or may be about 1:100, having about 0.01 second for ejection and about 1 second for non-ejection; or may be about 1:10, having about 0.1 second for ejection and about 1 second for non-ejection; or may be about 1:1, having about 1 second for ejection and about 1 second for non-ejection; or may be about 10:1, having about 1 second for ejection and about 0.1 second for non-ejection, or may be about 100:1, having about 1 second for ejection and about 0.01 second for non-ejection; or may be about 1000:1, having about 10 seconds for ejection and about 0.01 second for non-ejection.

In some embodiments, the gas ejection may be on and off for a plurality of times and/or for a period of time of about three to four hours, until the amorphous semiconductor of the amorphous semiconductor layer 21, in the gas-receiving region, is fully converted to polycrystalline semiconductor.

In one embodiment, after a gas ejection process, the disclosed apparatus for semiconductor polycrystallization may move to a suitable position so that the ejector outlets 11 can be facing a region, of the amorphous semiconductor layer 21, which has not been converted to polycrystalline semiconductor, and start ejecting heated gas over the region. Because the disclosed apparatus may only be able to polycrystallize a portion of the amorphous semiconductor substrate in one polycrystallization process, moving the disclosed apparatus may convert the amorphous semiconductor of the entire amorphous semiconductor substrate to polycrystalline semiconductor.

In some embodiments, when the disclosed apparatus for semiconductor polycrystallization is used to eject heated gas to the amorphous semiconductor substrate, the temperature of the heated gas may be configured based on the material of the amorphous semiconductor substrate. For example, the amorphous semiconductor substrate may be an amorphous-silicon semiconductor substrate. The temperature of the heated gas for polycrystallization may be in the range of about 800° C. or higher, for example, about 800° C. to about 1420° C. In another example, the amorphous semiconductor structure may include an amorphous oxide semiconductor, such as an indium gallium zinc oxide (IGZO) semiconductor substrate. Accordingly, the temperature of the heated gas for the polycrystallization of the amorphous oxide semiconductor may be higher than about 300° C., for example, higher than about 450° C. for IGZO. In still another example, the amorphous oxide semiconductor may be annealed for a certain period of time at a temperature, e.g., about 200° C. or higher.

It should be understood that the above embodiments disclosed herein are exemplary only and not limiting the scope of this disclosure. Without departing from the spirit and scope of this disclosure, other modifications, equivalents, or improvements to the disclosed embodiments are obvious to those skilled in the art and are intended to be encompassed within the scope of the present disclosure.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. An apparatus for semiconductor polycrystallization, comprising:
a plurality of ejector outlets for ejecting a heated gas to polycrystallize an amorphous semiconductor to produce a polycrystalline semiconductor.

2. The apparatus according to claim 1, wherein:
one ejector outlet corresponds to a gas-receiving region on the amorphous semiconductor and corresponds to a non-gas-receiving region neighboring the gas-receiving region on the amorphous semiconductor such that amorphous semiconductor in the gas-receiving region is converted into polycrystalline semiconductor by the heated gas; and
a diffusion rate of heat generated by the heated gas ejected by the ejector outlet from the gas-receiving region to the non-gas-receiving region is fast enough so that a gas-receiving region of a substrate deposited with the amorphous semiconductor is undamaged by the heated gas.

3. The apparatus according to claim 2, wherein the diffusion rate of heat generated by the heated gas ejected by the ejector outlet is associated with dimensions of the ejector outlet and a distance between two adjacent ejector outlets.

4. The apparatus according to claim 3, wherein a ratio of a total area of gas-receiving regions correspond to the plurality of ejector outlets to a total area of non-gas-receiving regions correspond to the plurality of ejector outlets is in a range of about 1:1000 to about 1000:1.

5. The apparatus according to claim 4, wherein the plurality of ejector outlets is arranged in an array.

6. The apparatus according to claim 1, further comprising a mask containing the ejector outlets.

7. The apparatus according to claim 6, wherein a ratio of a total area of the plurality of ejector outlets over a total area of areas other than the ejector outlets on the mask is in a range from about 1:1000 to about 1000:1.

8. The apparatus according to claim 6, further comprising a spray gun for spraying heated gas over a large area on the mask.

9. The apparatus according to claim 2, further comprising a cooling apparatus for cooling down the substrate deposited with the amorphous semiconductor.

10. The apparatus according to claim 1, wherein the amorphous semiconductor includes at least one of an amorphous silicon and an amorphous oxide.

11. The apparatus according to claim 10, wherein a temperature of the heated gas is higher than about 800° C. for converting the amorphous silicon into a polycrystalline silicon.

12. The apparatus according to claim 10, wherein a temperature of the heated gas is higher than about 300° C. for converting the amorphous oxide into a polycrystalline oxide.

13. The apparatus according to claim 10, wherein a temperature of the heated gas is higher than about 200° C. for annealing the amorphous oxide.

14. A method for semiconductor polycrystallization, comprising: using the apparatus of claim 1 to eject the heated gas on the amorphous semiconductor to polycrystallize the amorphous semiconductor into the polycrystalline semiconductor.

15. The method according to claim 14, further comprising:
periodically ejecting the heated gas to the amorphous semiconductor.

16. The method according to claim 15, wherein:
the periodically ejecting includes a ratio of an ejecting time length over a non-ejecting time length of about 1:10000 or greater.

17. The method according to claim 14, further comprising:
moving the apparatus, after one ejection process that converts a portion of the amorphous semiconductor into the polycrystalline semiconductor, to anther portion of the amorphous semiconductor to convert the another portion of the amorphous semiconductor into another portion of the polycrystalline semiconductor.

18. The method according to claim 14, wherein the amorphous semiconductor is made of an amorphous silicon and a temperature of the heated gas for the polycrystallization is higher than about 800° C.

19. The method according to claim 14, wherein the amorphous semiconductor is made of an amorphous oxide semiconductor and a temperature of the heated gas for the polycrystallization is above about 300° C.

20. The method according to claim 14, wherein the amorphous semiconductor is made of an amorphous oxide semiconductor and a temperature of the heated gas for annealing the amorphous oxide semiconductor is higher than about 200° C.
